(19) United States
(12) Patent Application Publication
(10) Pub. No.: US 2005/0270727 A1
(43) Pub. Date: Dec. 8, 2005

(54) Loading cartridge latch structure

(76) Inventor: Shoei-Yuan Shih, Shijr City (TW)

Correspondence Address: BIRCH STEWART KOLASCH & BIRCH, PO BOX 747, FALLS CHURCH, VA, 22040-0747, US

(21) Appl. No.: 10/861,346

(22) Filed: Jun. 7, 2004

(51) Int. Cl. H05K 5/00

(52) U.S. Cl. 361/679

(57) ABSTRACT

A removable mechanism for electronic devices includes: a removable body coupled to a removable box. The removable body is turned on the removable box. A coupling member is located between the removable body and the removable box. The coupling member has an elastic section to turn the removable body to a desired displacement. The coupling member has a latch to couple with a latch lug of the removable body to fix the removable body to the removable box.

### FIELD OF THE INVENTION

The present invention relates to a removable mechanism for electronic devices and particularly to a removable mechanism that employs a coupling member to turn a removable body on a removable box to a desired displacement anchoring the removable body to the removable box.

### BACKGROUND OF THE INVENTION

Removable boxes have been widely used on modules such as hard disk drives, optical disk drives or control cards to facilitate carrying, replacement, repairs, and maintenance. Basically a removable box includes a shell disposed on a computer host case to house and anchor a hard disk drive, optical disk drive or control card. Once the removable box is inside the shell, the shell may be fastened to the computer host through a locking means located on the shell.

Refer to FIG. 1 for a handle seat 10 and a removable body 14 of a conventional removable mechanism. The removable mechanism is anchored to a case (not shown in the drawing). The case is for housing a personal computer, server or disk drive array. The removable mechanism includes a removable box (not shown in the drawing), a handle seat 10 and a removable body 14. The handle seat 10 is coupled with a conductive connection frame 11 on a rear side. The conductive connection frame 11 has a jutting coupling blade 13 corresponding to a recess 12 formed on the handle seat 10 to prevent electromagnetic interference (EMI). The handle seat 10 has one end holding a spring 15 which is pivotally coupled with the removable body 14 through an axle 16. The removable body 14 has a stopper section 17 at one end where the axle 16 is located to form a positioning constraint with the case. The removable body 14 has another end forming a latch section 18. The handle seat 10 has a retaining element 19 corresponding to the latch section 18. The spring 15 enables the removable body 14 to turn smoothly on the handle seat 10. The latch section 18 may be coupled on the retaining element 19 to anchor the removable body 14 to the handle seat 10 to complete assembly of the removable mechanism.

As previously discussed, the conventional removable mechanism uses the spring 15 and latch section 18 and retaining element 19 to turn and anchor the removable body 14 on the removable box. As the spring 15, latch section 18 and the retaining element 19 are made from different materials, different molds have to be prepared for their fabrication. As a result, costs are higher. During assembly, the spring 15 has to be coupled between the removable body 14 and the handle seat 10. It is an inconvenient process. Finally, when the removable body 14 is pushed out by the spring 15 for removable, the elastic force of the spring 15 often turns the removable body 14 a greater distance than required, hence the removable body 14 has to be opened and removed from the removable box in a greater space. Thus making inefficient use of space.

### SUMMARY OF THE INVENTION

Therefore the primary object of the present invention is to provide a removable mechanism that is simple to manufacture. A coupling member is provided between a removable body and a removable box that has an elastic section for turning the removable body on the removable box to a desired displacement and a latch for anchoring the removable body to the removable box. The latch is coupled with a lug on the removable body. The coupling member of the invention combines the functions of the spring and retaining element in the conventional removable mechanism, reducing the number of required elements.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is an exploded view of a conventional technique.

FIG. 2 is a perspective view of the present invention.

FIG. 3 is an exploded view of the present invention.

FIG. 4 is a schematic view of the present invention in a use condition.

FIG. 5A is a schematic view of the removable mechanism and the case of the present invention in an operating condition.

FIG. 5B is a schematic view of the removable mechanism and the case of the present invention in another operating condition.

FIG. 5C is a schematic view of the removable mechanism and the case of the present invention in yet another operating condition.

FIG. 6A is a schematic view of the coupling member and the removable body in an operating condition.

FIG. 6B is a schematic view of the coupling member and the removable body in another operating condition.

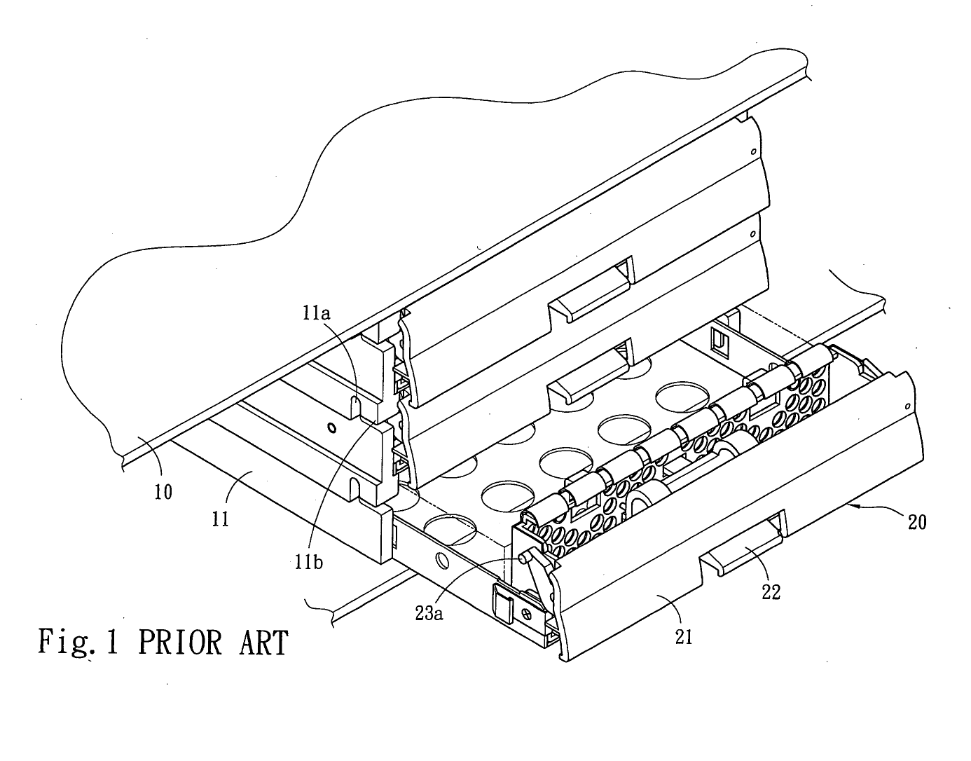

### DETAILED DESCRIPTION OF THE PREFERRED EMBODIMENT

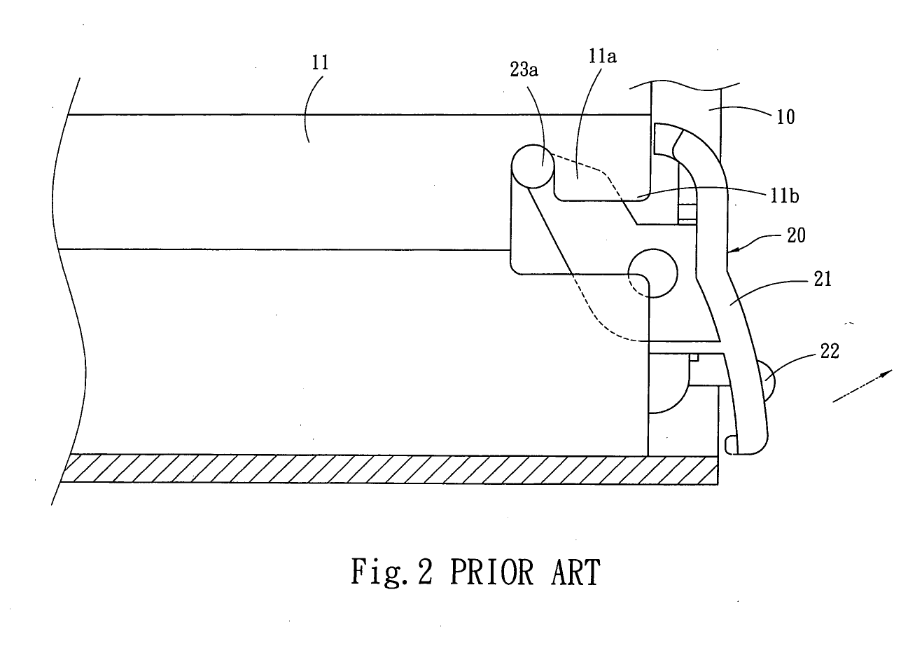

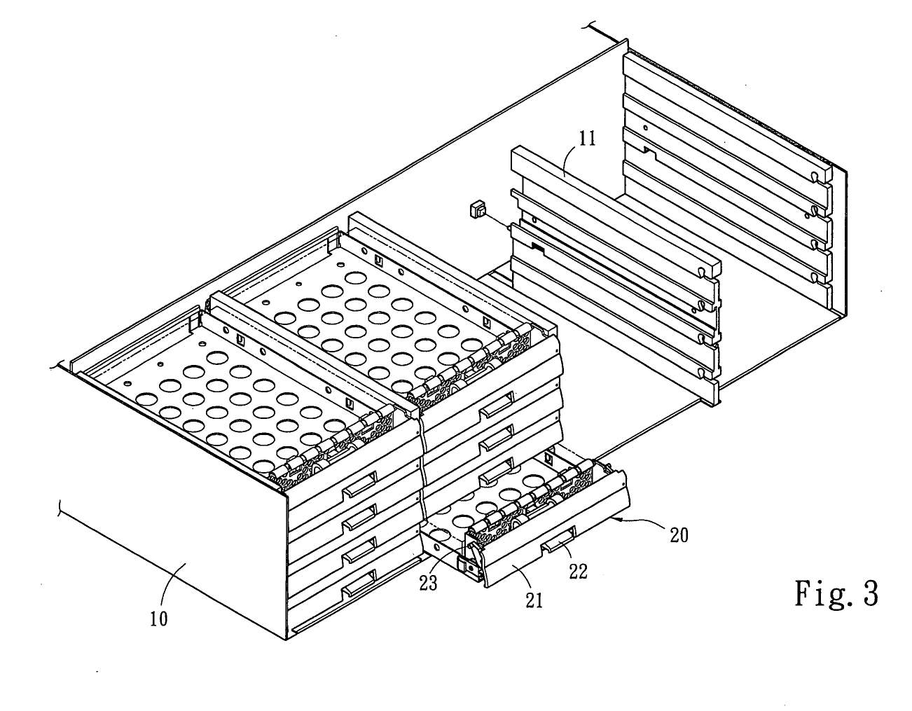

Please referring to FIGS. 2 and 3, the removable mechanism 20 includes a removable box 30 and a removable body 40. By applying a force to the removable body 40, the removable box 30 may be removed for removable. The removable box 30 has an end plate 31 at the front end. There is a housing compartment 33 located between the end plate 31 and the removable body 40. A coupling member 60 is provided and located in the housing compartment 33 that has a latch lug 61 located on a rear end thereof engaging with an opening 311 formed on the end plate 31. The coupling member 60 further has a positioning section 62 to aid the anchoring of the latch lug 61 so that there is no swaying after the coupling member 60 is latched to the end plate 31. In addition, the end plate 31 is coupled with a conductive connection plate 51 on the rear side. The conductive connection plate 51 has a latch hole 514 to couple with the latch lug 61 of the coupling member 60. The conductive connection plate 51 has latch claws 511 on an upper side and bottom hooks 515 on a lower side and elastic reeds 512 on the lateral sides to guard against EMI, Electromagnetic Interference (the connection method and utilization are known in the art, and form no part of the invention, thus details are omitted). The removable body 40 is located in front of the end plate 31. It has flank blades 41 on two sides to couple with fastening sections 32 on two sides of the end plate 31. Each flank blade 41 and the fastening section 32 have respectively an aperture 411 and 321 coupled with an axle 50 so that the removable body 40 is turned on the end plate 31. When the removable body 40 is turned, it is moved to a full displacement through the elastic section 63 of the coupling member 60. The removable body 40 and the coupling member 60 have respectively a latch lug 42 and a latch section 64 that may be coupled to provide anchoring function. Finally, a fastener 66 runs through apertures 513, 341 and 312 formed respectively on the elastic reed 512, a sliding section 34 of the removable box 30 and the jutting plate 314 for fastening the three elements.

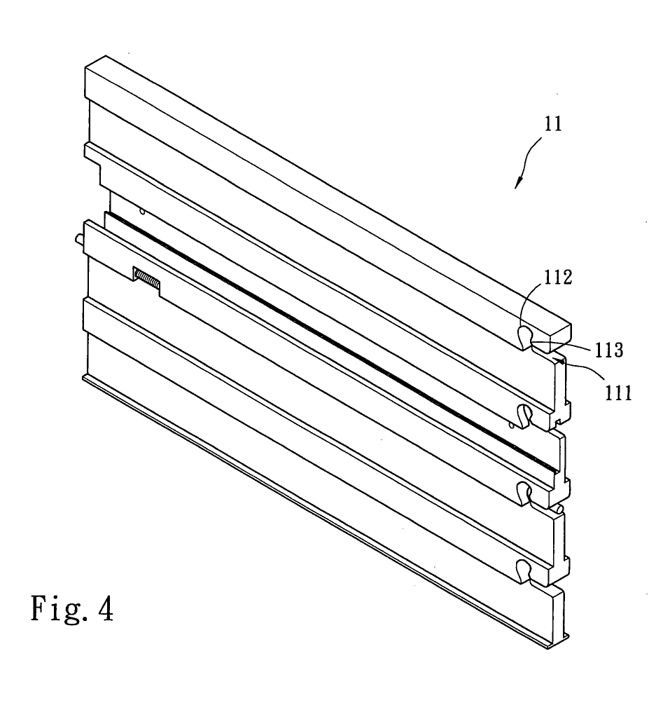

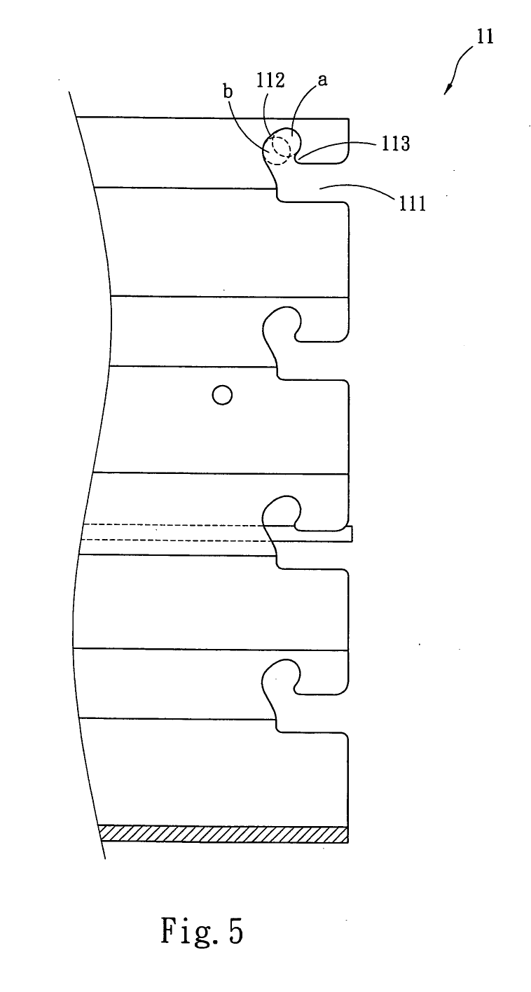

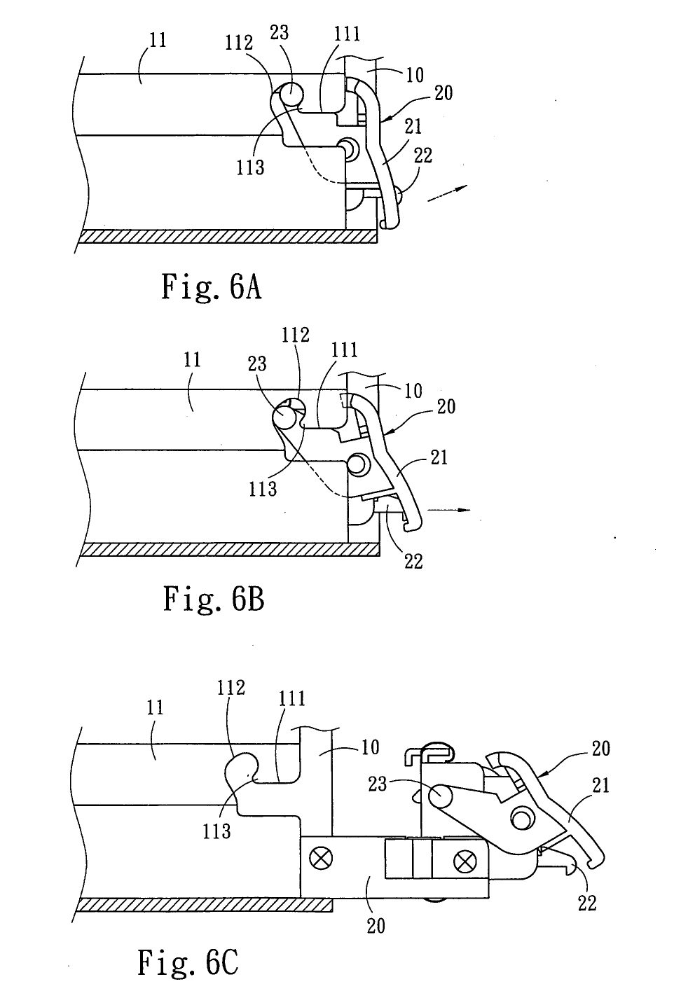

Referring to FIGS. 4, 5A, 5B and 5C, when in use, the removable box 30 houses an electronic device 65. For loading the removable mechanism 20 into the case 52, first, turn the removable body 40 upwards to make a distal end side 412 of the flank blade 41 lower than a hook 521 of the case 52, and push forwards (shown by an arrow in the drawings) to enter a latch inset 522. When the removable box 30 completely enters the case 52, in order to prevent the removable box 30 from hitting electronic elements located on the rear side of the case 52, a stopper 43 will press the surface of the case 52. Meanwhile, turn the removable body 40 downwards to move the distal end side 412 of the flank blade 41 into the latch inset 522 to be anchored by the hook 521. Consequently the removable box 30 is anchored to the case 52. Coupling member 60 located in the housing compartment 33 (also referring to FIGS. 6A and 6B) latches to the removable body 40. When the removable body 40 is turned, the elastic section 63 moves the removable body 40 to the full turning displacement. When the removable body 40 is turned downwards first, the elastic section 63 is rammed inwards and bent in a concave manner to store a returning force for the coupling member 60 in the anchoring condition. When the latch lug 42 of the removable body 40 slides over the sloped surface 641 of the latch section 64, it pushes the latch section 64 slightly downwards, and then latches. For releasing, first press the sloped surface 641 to move the latch section 64 downwards (referring to FIG. 6A), the stored returning force mentioned before unlatches the removable body 40 from the anchoring condition so that the latch lug 42 separates from the latch section 64. Then the removable body 40 may be turned upwards to remove the removable box 30 from the case 52.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

1. An removable mechanism for electronic devices located on a removable box for moving the removable box, comprising:
a removable body located on a front end of the removable box; and
a coupling member coupled on the removable box located between the removable body and the removable box to anchor the removable body to the removable box, storing a returning force in the anchoring condition for pushing the removable body to a free condition when the removable body is released from the coupling and anchoring condition.

2. The removable mechanism of claim 1, wherein the removable box has an end plate on a front end thereof, the end plate having two sides each having a fastening section for fastening the removable body to the removable box and an opening for coupling with the coupling member, the coupling member having a latch lug to couple with the opening, the end plate and the removable body forming a housing compartment to house the coupling member.

3. The removable mechanism of claim 1, wherein the coupling member is extended to form an elastic section and a latch, the removable body being turned to a desired displacement through the elastic section and having a latch lug mating the latch to anchor the removable body.

4. The removable mechanism of claim 2, wherein the end plate is coupled with a conductive connection plate on a rear side thereof to prevent electromagnetic interference.

5. The removable mechanism of claim 1, wherein the coupling member further has a positioning section. The removable mechanism of claim 1, wherein the removable body has two sides each having a flank blade which has an aperture to couple with the removable box.
